(19) United States
(12) Patent Application Publication
(10) Pub. No.: US 2011/0155453 A1
(43) Pub. Date: Jun. 30, 2011

(54) ELECTRONIC APPARATUS

(75) Inventors: Yasutoshi Kawai, Osaka (JP); Takahiro Kitai, Osaka-shi, Osaka (JP)

(73) Assignee: SANYO ELECTRIC CO., LTD., Osaka (JP)

(21) Appl. No.: 12/977,855

(22) Filed: Dec. 23, 2010

(30) Foreign Application Priority Data
Dec. 28, 2009 (JP) 2009-297715

(51) Int. Cl. H05K 7/20

(52) U.S. Cl. 174/547

(57) ABSTRACT

A video camera according to an embodiment of this invention includes a chassis that is fixed within a casing, a CMOS image sensor that is installed in the chassis, and a heat releasing member that releases heat generated from the CMOS image sensor to outside the casing. The heat releasing member extends along at least an area of one part of an inner face of the casing, and is adjacent to or in contact with the area. One part of the chassis contacts the rear face of the heat releasing member.

This patent application claims priority to Japanese Patent Application No. 2009-297715, the contents of which are hereby incorporated in its entirety by reference into the present application.

### BACKGROUND OF THE INVENTION

1. Field of the Invention

The present invention relates to an electronic apparatus such as a camera or a mobile phone.

2. Description of the Related Art

This kind of electronic apparatus includes a chassis that is fixed within a casing, and an electronic component that is installed in the chassis. An electronic apparatus has been proposed in which a heat releasing member is installed within the casing in order to release heat generated from an electronic component when executing a device operation to outside the casing.

For example, a circuit board on which various electronic components are mounted is installed in the chassis, and the electronic components on the circuit board and a heat releasing member are coupled by a heat conductive sheet. Thus, heat that is generated from the electronic components on the circuit board is conducted to the heat releasing member through the heat conductive sheet, and is released to outside the casing from the heat releasing member.

In a conventional electronic apparatus, in order to prevent the casing of the electronic apparatus from undergoing plastic deformation when a large pressing force is applied to the casing, a reinforcing member that reinforces the casing is installed on the inside or outside of the casing to enhance the rigidity of the casing.

However, in conventional electronic apparatus it has been necessary to provide two separate members, namely, a heat releasing member and a reinforcing member, in order to enhance both a heat releasing property and the rigidity of the casing of the electronic apparatus. Accordingly, the number of components constituting the electronic apparatus increases, and as a result there have been the problems that the process of assembling the electronic apparatus is complicated and the size of the electronic apparatus increases.

### SUMMARY OF THE INVENTION

An electronic apparatus according to the present invention includes a chassis that is fixed within a casing, an electronic component installed in the chassis, and a heat releasing member that releases heat generated from the electronic component to outside the casing. The heat releasing member extends along at least an area of one part of an inner face of the casing and is adjacent to or in contact with the area, and a portion of the chassis contacts a rear face of the heat releasing member. Accordingly, heat generated from the electronic component is released to outside the casing through the heat releasing member.

### BRIEF DESCRIPTION OF THE DRAWINGS

FIG. 1 is a perspective view, as seen from the front side, of a video camera that is an embodiment of the present invention in a second open state;

FIG. 2 is a perspective view, as seen from a back face side, of the video camera in the second open state;

FIG. 3 is a side view of the second open state of the video camera;

FIG. 4 is a front view of a first open state of the video camera;

FIG. 5 is a back view of a closed state of the video camera;

FIG. 6 is an exploded perspective view of a first casing that is included in the video camera;

FIG. 7 is a cross-sectional view taken along the line A-A shown in FIG. 6;

FIG. 8 is an exploded perspective view that illustrates an image pickup unit, a heat releasing member, and an upper chassis portion that are included in the video camera;

FIG. 9 is a perspective view illustrating an assembled state of the image pickup unit, the heat releasing member, and the upper chassis portion; and

FIG. 10 is a perspective view illustrating an assembled state of the heat releasing member and the upper chassis portion.

### DETAILED DESCRIPTION OF THE PREFERRED EMBODIMENTS

Hereinafter, embodiments of the present invention implemented on a video camera capable of shooting a still image and a moving image will be described in detail with reference to the drawings.

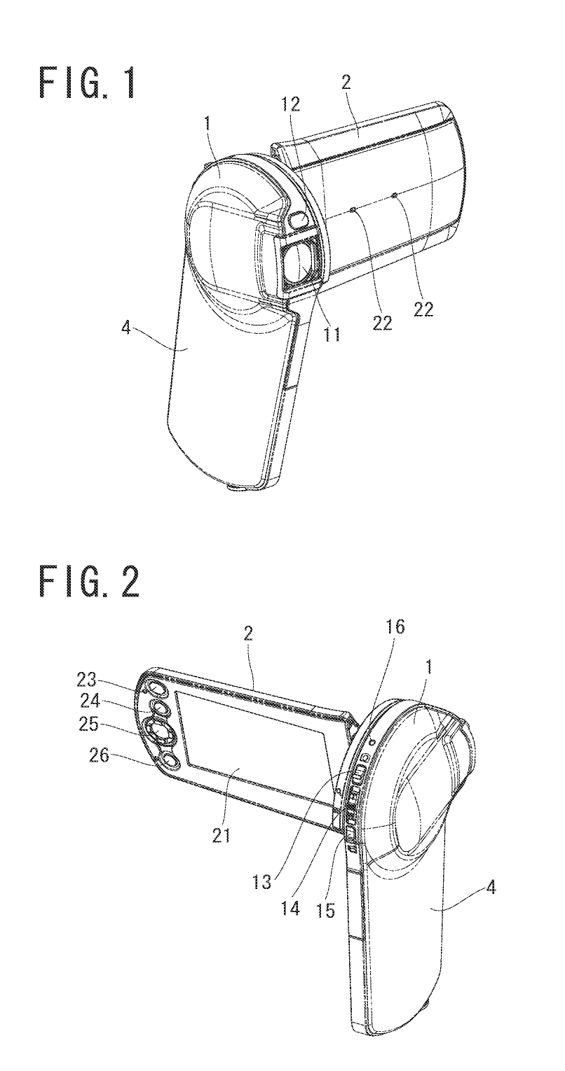

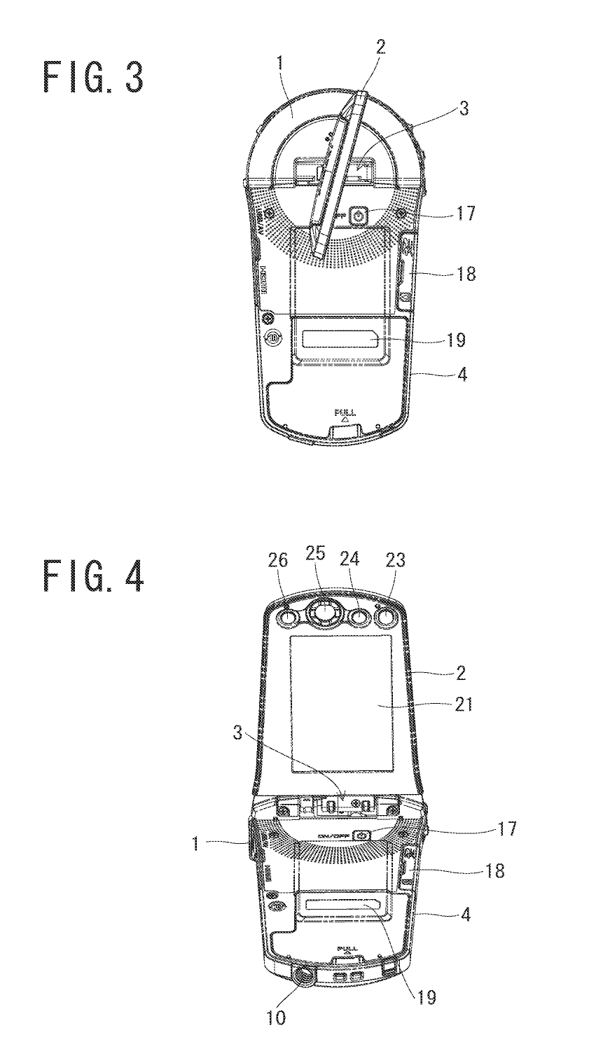

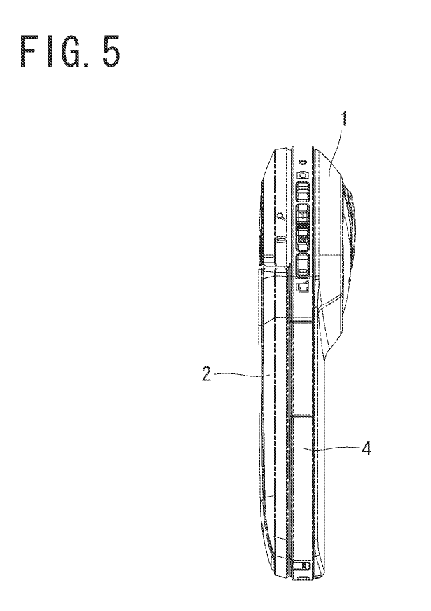

As illustrated in FIGS. 1 and 2, a video camera that is an embodiment of the present invention includes a first casing 1 and a second casing 2. The two casings 1 and 2 are coupled with each other so as to be openable and closeable by a biaxial hinge mechanism 3 as shown in FIG. 3. The video camera can be set to a closed state in which the second casing 2 is closed with respect to the first casing 1 as illustrated in FIG. 5, a first open state in which the second casing 2 is opened with respect to the first casing 1 as illustrated in FIG. 4, and a second open state in which the second casing 2 is rotated from the first open state as illustrated in FIGS. 1 to 3.

As illustrated in FIG. 5, a grip portion 4 is formed in the first casing 1 in an area that faces the second casing 2 when the video camera has been set in the closed state. As illustrated in FIGS. 1 to 3, a user uses the video camera by setting the video camera in the second open state and gripping the grip portion 4 with a hand.

Further, as illustrated in FIG. 4, a mounting seat 10 for mounting the video camera on a tripod (not shown) is provided on the bottom of the first casing 1. A female screw into which a male screw formed on the tripod is screwed is formed in the mounting seat 10. The female screw is exposed from the bottom face of the first casing 1. Mounting the video camera on a tripod utilizing the mounting seat 10 allows the video camera to be placed on a floor or the ground and used.

As illustrated in FIG. 1, a shooting lens 11 and an LED (Light Emitting Diode) for illumination 12 are provided on a front part of the first casing 1. In addition, as illustrated in FIG. 2, a shutter button 13 and a zoom button 14 that are used to input an instruction for still image shooting, a recording button 15 that is used to input an instruction for moving image shooting, and an access lamp 16 are provided on a rear part of the first casing 1.

Further, as illustrated in FIGS. 3 and 4, a power button 17, a card cover 18, and a battery cover 19 are provided on a surface of the grip portion 4 of the first casing 1 in an area that is covered by the second casing 2 when the video camera has been set in the closed state.

As illustrated in FIG. 1, a pair of microphones 22 and 22 are provided on an outer face of the second casing 2. Further, as illustrated in FIG. 2, a liquid crystal display 21 is provided on an inner face of the second casing 2. A record/playback key 23, a menu key 24, a cross key 25, and a set key 26 are also provided on the inner face of the second casing 2 in a different area to the area in which the liquid crystal display 21 is provided. A plating process is performed on the outer face of the second casing 2.

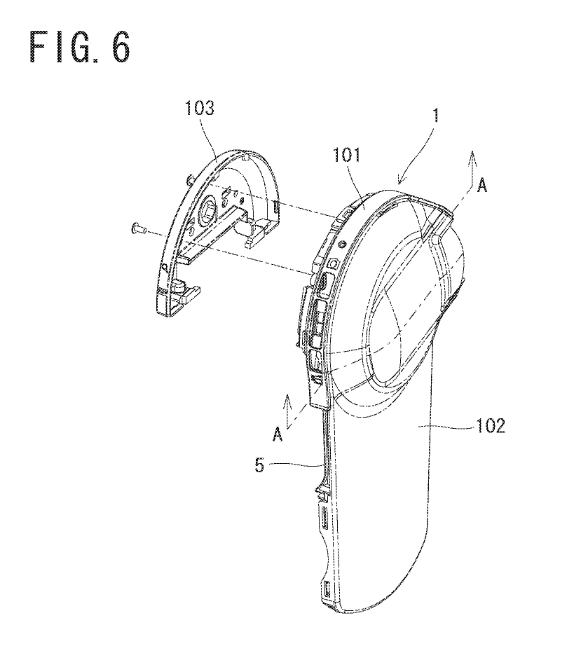

As illustrated in FIG. 6, the first casing 1 is formed by attaching to a chassis 5 a first cabinet component 101 that constitutes a curved upper face wall of the first casing 1, a second cabinet component 102 that constitutes a wall on the right side face of the first casing 1 of FIG. 6, and a third cabinet component 103 that constitutes a wall on the left side face of an upper portion of the first casing 1 of FIG. 6. The first cabinet component 101 and the third cabinet component 103 are made of synthetic resin. The second cabinet component 102 is made of aluminum.

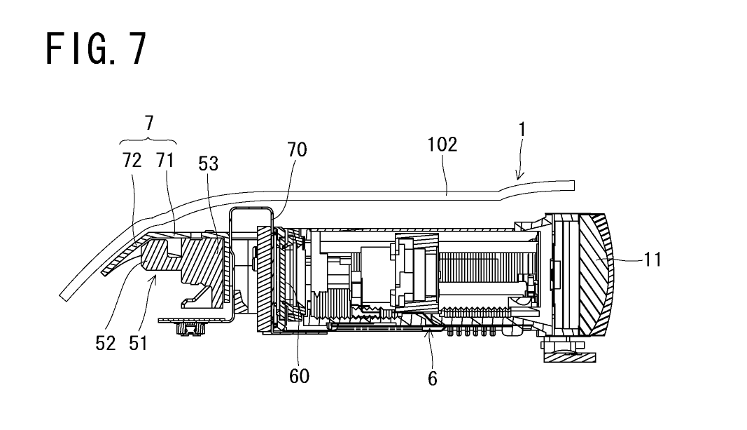

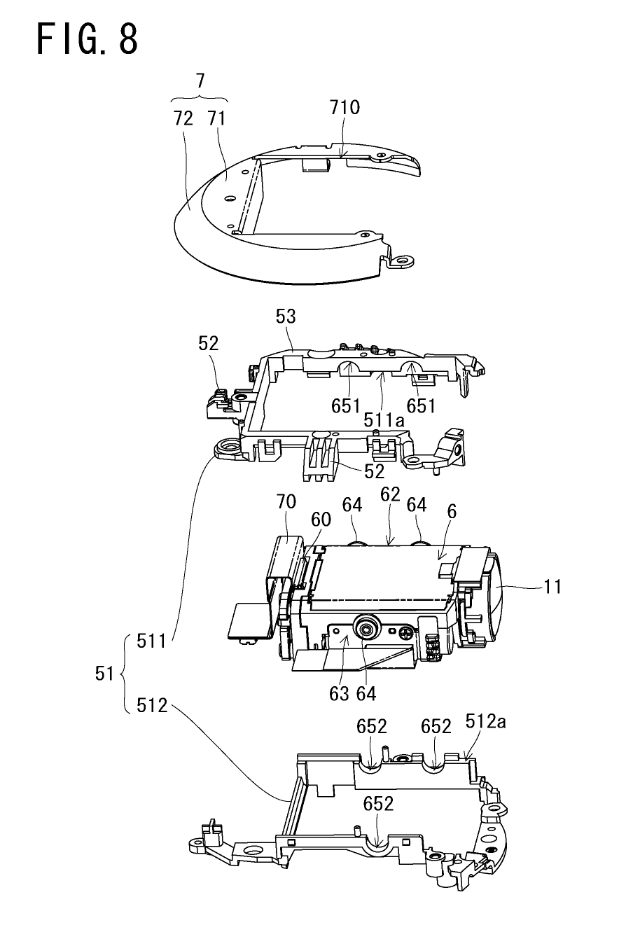

As illustrated in FIG. 7, the chassis 5 has an upper chassis portion 51 that is fixed to an inner area of the upper portion of the first casing 1. As illustrated in FIG. 8, the upper chassis portion 51 is formed by joining together a first frame body 511 and a second frame body 512. The first frame body 511 and the second frame body 512 are made of synthetic resin.

As illustrated in FIG. 7, an image pickup unit 6 that includes the shooting lens 11 is provided in an internal area in the upper portion of the first casing 1. The image pickup unit 6 includes a CMOS (Complementary Metal Oxide Semiconductor) image sensor 60. A copper foil 70 is connected to the CMOS image sensor 60. A large amount of heat is generated from the CMOS image sensor 60 when the image pickup unit 6 is driven.

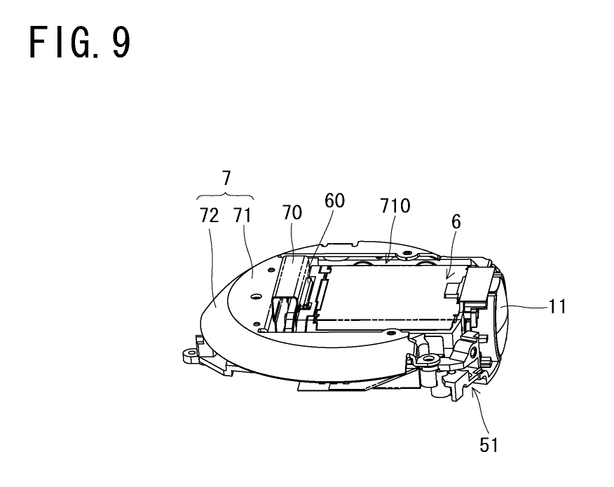

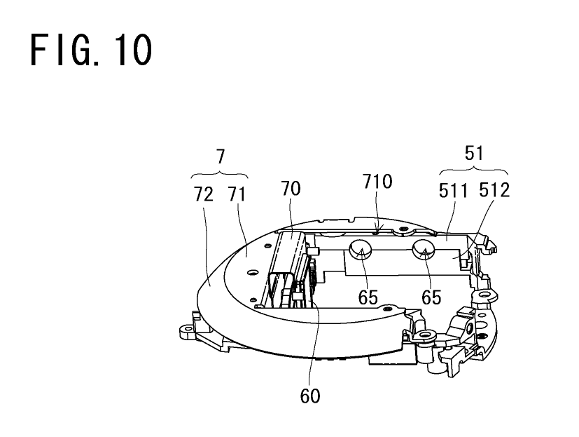

As illustrated in FIG. 9, the image pickup unit 6 is fitted into the first frame body 511 and the second frame body 512 that form the upper chassis portion 51. As illustrated in FIG. 8, two engagement portions 64 and 64 are protrudingly provided on an upper face 62 of the image pickup unit 6, and one engagement portion 64 is protrudingly provided on a lower face 63 of the image pickup unit 6. Pairs of groove portions 651 and 652 are recessed into respective joint surfaces 511a and 512a between the first frame body 511 and the second frame body 512. The pairs of groove portions 651 and 652 face each other in correspondence with the respective engagement portions 64. Further, as illustrated in FIG. 10, in a state in which the two frame bodies 511 and 512 are joined together, engagement receiving portions 65 with which the respective engagement portions 64 are to engage are formed by pairs of groove portions 651 and 652 that correspond to the relevant engagement portions.

In the process of assembling the video camera, the respective engagement portions 64 of the image pickup unit 6 are fitted into the pair of groove portions 651 and 652 corresponding to the relevant engagement portion 64 and the first frame body 511 and the second frame body 512 are joined together. Thus, each engagement portion 64 of the image pickup unit 6 engages in the engagement receiving portion 65 corresponding to the relevant engagement portion 64, and as a result the image pickup unit 6 is attached to the upper chassis portion 51.

As illustrated in FIG. 7, a heat releasing member 7 is also provided in an internal area in the upper portion of the first casing 1. The heat releasing member 7 releases heat generated from the CMOS image sensor 60 of the image pickup unit 6 to outside the first casing 1. The heat releasing member 7 is made of copper.

As illustrated in FIGS. 8 and 9, a flat portion 71 and a curved portion 72 that has a curved surface that extends from an outer edge of the flat portion 71 are formed in the heat releasing member 7 by bendingly deforming the heat releasing member 7. As illustrated in FIG. 7, the curved portion 72 is formed along at least an area of one part of an inner face of the second cabinet component 102, and is adjacent to the relevant area.

As illustrated in FIG. 10, the heat releasing member 7 is attached to the first frame body 511, and one portion of the first frame body 511 contacts the rear face of the flat portion 71 and the curved portion 72 of the heat releasing member 7. More specifically, as illustrated in FIG. 8, a plurality of ribs 52 to 52 are formed on an outer circumferential face of a frame main body 53 of the first frame body 511. As illustrated in FIG. 7, each rib 52 has a shape such that a distal end face thereof is formed along the rear face of the curved portion 72 of the heat releasing member 7. The frame main body 53 of the first frame body 511 contacts against the rear face of the flat portion 71 of the heat releasing member 7, and the distal end face of each rib 52 contacts against the rear face of the curved portion 72 of the heat releasing member 7.

As illustrated in FIG. 9, an opening 710 is formed in the flat portion 71 of the heat releasing member 7. The image pickup unit 6 is arranged inside the opening 710. As illustrated in FIG. 7, the copper foil 70 that is connected to the CMOS image sensor 60 is connected to the heat releasing member 7. Accordingly, heat generated from the CMOS image sensor 60 is efficiency conducted to the heat releasing member 7 through the copper foil 70.

In the above described video camera, heat generated from the CMOS image sensor 60 is released to outside the first casing 1 through the heat releasing member 7. Accordingly, damage to the CMOS image sensor 60 caused by overheating is prevented.

Furthermore, in the video camera, if a large pressing force is applied to the second cabinet component 102 of the first casing 1, the second cabinet component 102 changes shape such that the second cabinet component 102 is pressed into the heat releasing member 7. In this case, a part of the upper chassis portion 51 (specifically, the first frame body 511) contacts the rear face of the heat releasing member 7, and the upper chassis portion 51 is fixed in an inner area of the upper portion of the first casing 1. Accordingly, the heat releasing member 7 can receive the second cabinet component 102 that has changed shape. Further, the heat releasing member 7 is provided in an extending condition adjacent to the inner face of the second cabinet component 102. Therefore, the amount of deformation of the second cabinet component 102 is only a small amount. Hence, even in a case in which a large pressing force is applied to the second cabinet component 102 and the second cabinet component 102 changes shape, the resulting deformation need only be an elastic deformation, and thus the second cabinet component 102 is prevented from undergoing a plastic deformation.

Moreover, the heat releasing member 7 extends along at least an area of one part of the inner face of the second cabinet component 102. Accordingly, a pressing force applied to the second cabinet component 102 is received over a wide range by the heat releasing member 7.

Hence, according to the above described video camera it is possible to enhance both the heat releasing property thereof and the rigidity of the second cabinet component 102 while reducing the number of components constituting the video camera.

Further, in the above described video camera, the flat portion 71 and the curved portion 72 are formed in the heat releasing member 7 by bendingly deforming the heat releasing member 7. By combining the flat portion 71 and the curved portion 72 in this manner, the rigidity of the heat releasing member 7 is enhanced.

It is to be understood that the present invention is not limited to the respective components and configuration described in the above embodiment and that various modifications will be apparent to those skilled in the art without departing from the spirit or scope of the following claims. For example, the above described video camera may have a configuration in which the heat releasing member 7 contacts the inner face of the first casing 1 (specifically, the inner face of the second cabinet component 102). Further, the video camera may have a configuration in which the flat portion 71 of the heat releasing member 7 is also adjacent to or contacting with the inner face of the first casing 1 (specifically, the inner face of the second cabinet component 102), similarly to the curved portion 72.

Further, the shape and installation location of the heat releasing member 7 is not limited to the above described embodiment, and various shapes and installation locations can be adopted with respect to the shape and installation location of the heat releasing member 7.

Furthermore, the various configurations adopted in the above described video camera are not limited to a video camera that includes the CMOS image sensor 60, and can be applied to various electronic apparatus that include an electronic component.

What is claimed is:

1. An electronic apparatus, comprising:
a chassis that is fixed within a casing;
an electronic component installed in the chassis; and
a heat releasing member that releases heat generated from the electronic component to outside the casing; wherein:
the heat releasing member extends along at least an area of one part of an inner face of the casing and is adjacent to or in contact with the area; and
a portion of the chassis contacts a rear face of the heat releasing member.

2. The electronic apparatus according to claim 1, wherein an opening is formed in the heat releasing member, and the electronic component is arranged inside the opening.

3. The electronic apparatus according to claim 1, wherein a flat portion and a curved portion that has a curved surface that extends from an outer edge of the flat portion are formed in the heat releasing member by bendingly deforming the heat releasing member, and the flat portion and/or curved portion is formed along the area of the inner face of the casing and is adjacent to or in contact with the area.

4. The electronic apparatus according to claim 3, wherein an opening is formed in the heat releasing member, and the electronic component is arranged inside the opening.
